(19) United States
(12) Patent Application Publication
(10) Pub. No.: US 2008/0044981 A1
(43) Pub. Date: Feb. 21, 2008

(54) Trench Isolation Methods, Methods of Forming Gate Structures Using the Trench Isolation Methods and Methods of Fabricating Non-Volatile Memory Devices Using the Trench Isolation Methods

(75) Inventors: Jung Geun Jee, Gyeonggi-do (KR); Won-Jun Jang, Seoul (KR); Woong Lee, Seoul (KR); Ho-Min Son, Gyeonggi-do (KR); Won-Jun Lee, Seoul (KR); Hyoeng-Ki Kim, Gyeonggi-do (KR); Jung-Hyun Park, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/769,042

(22) Filed: Jun. 27, 2007

(30) Foreign Application Priority Data
Jul. 7, 2006 (KR) 10-2006-0063897

(51) Int. Cl. H01L 21/3205; H01L 21/762

(52) U.S. Cl. 438/424; 438/594; 257/E21.294; 257/E21.546

(57) ABSTRACT

Methods of fabricating semiconductor devices including forming a mask pattern on a semiconductor substrate are provided. The mask pattern defines a first opening that at least partially exposes the semiconductor substrate and includes a pad oxide layer and a nitride layer pattern on the pad oxide layer pattern. The nitride layer has a line width substantially larger than the pad oxide layer pattern. A second opening that is connected to the first opening is formed by at least partially removing a portion of the semiconductor substrate exposed through the first opening. The second opening has a sidewall that has a first inclination angle and at least partially exposing the semiconductor substrate. A trench connected to the second opening is formed by etching a portion of the semiconductor substrate exposed through the second opening using the mask pattern as an etch mask. The trench is substantially narrower than the second opening and has a sidewall that has a second inclination angle that is substantially larger than the first inclination angle.

### CLAIM OF PRIORITY

This application is related to and claims priority from Korean Patent Application No. 10-2006-0063897 filed on Jul. 7, 2006, in the Korean Intellectual Property Office, the disclosure of which is hereby incorporated herein by reference as if set forth in its entirety.

### FIELD OF THE INVENTION

The present invention generally relates to semiconductor devices and, more particularly, to semiconductor devices and related methods of fabrication.

### BACKGROUND OF THE INVENTION

Generally, semiconductor memory devices are classified as either volatile memory devices or non-volatile memory devices. Volatile memory devices may include, for example, dynamic random access memory (DRAM) devices and static random access memory (SRAM) devices. The data input speed and data output speed of the volatile memory device are typically relatively fast. However, data stored in the non-volatile memory device is not retained when power is removed from the device. Non-volatile memory devices may include, for example, read only memory (ROM) devices, such as electrically erasable programmable read only memory (EEPROM) devices. Recently, flash memory devices, a type of EEPROM device, have become widely used. Data input speed and data output speed of flash memory devices are relatively slow. However, flash memory devices retain data when power is removed from the device. In order to program and/or erase data, flash memory devices use, for example, Fowler-Nordheim tunneling or hot electron injection.

Conventional flash memory devices typically include a gate structure including a tunnel oxide layer pattern on an active region of a semiconductor substrate, such as a silicon wafer, a floating gate electrode, a dielectric layer pattern and a control gate electrode.

A tunnel oxide layer, a first conductive layer, a dielectric layer and a control gate electrode are successively formed on the substrate to form the gate structure. Thereafter, the tunnel oxide layer, the first conductive layer, the dielectric layer and the control gate electrode are successively etched to provide the gate structure. However, an alignment margin between a gate mask used for forming the gate structure and an active region defined by an insulating layer may decrease due to an increase in integrity. To address this problem, a self-alignment method may be used.

Polysilicon may be used while performing the self-alignment method. In particular, a mask pattern having a first hole exposing a substrate may be initially formed on the substrate. The substrate may then be etched by using the mask pattern as an etch mask so that a trench is formed at a surface of the substrate. Thereafter, an insulating layer pattern is provided in the first opening and the trench is formed. The mask pattern is then removed so that a second opening exposes at least a portion of an active region, i.e., a portion of the substrate covered by the mask pattern, is formed between the insulating layer patterns. A tunnel oxide layer is then formed on the active region. Thereafter, polysilicon doped with impurities is provided in the second opening to form a floating gate electrode aligned to the active region.

In the above self-alignment method, the tunnel insulating layer is typically formed by a thermal oxidation process. When the tunnel insulating layer is formed, a stress due to a three dimensional effect may be applied to both edge portions of the active region. Thus, an oxidation of the edge portion may be relatively smaller than that of a center portion. As a result, a portion of the tunnel oxide layer located on the edge portion may be relatively thinner than a portion of the tunnel oxide layer located on the center portion.

If a thickness of the tunnel oxide layer is not relatively uniform, a current leakage may be generated at the edge portion. Furthermore, an electron tunnel may be generated at a voltage substantially smaller than a threshold voltage. Thus, a lasting quality of the tunnel oxide layer and a data retaining capacity of the floating gate electrode may be compromised. As a result, reliability of the non-volatile memory device may decrease.

The problems due to the irregular thickness of the tunnel oxide layer may be addressed by allowing the active region to have a slightly inclined edge portion. A conventional method making the edge portion gently inclined by partially oxidizing the active region is disclosed in Korean Patent Laid-Open Publication No. 2006-002534.

In the conventional method, a mask pattern is formed on a substrate. An exposed portion of the substrate is partially oxidized and then the substrate is selectively removed. An oxidizing process and a removal process are repeatedly performed, thereby making an edge of the substrate that is contacted with the mask pattern to be slightly inclined.

However, even using the conventional method discussed above fabricating a device having a slightly inclined edge portion may be difficult. Thus, improved methods of a fabricating the edge portion having a slight incline may be desirable.

### SUMMARY OF THE INVENTION

Some embodiments of the present invention provide methods of fabricating semiconductor devices including forming a mask pattern on a semiconductor substrate. The mask pattern defines a first opening that at least partially exposes the semiconductor substrate and includes a pad oxide layer and a nitride layer pattern on the pad oxide layer pattern. The nitride layer has a line width substantially larger than the pad oxide layer pattern. A second opening that is connected to the first opening is formed by at least partially removing a portion of the semiconductor substrate exposed through the first opening. The second opening has a sidewall that has a first inclination angle and at least partially exposing the semiconductor substrate. A trench connected to the second opening is formed by etching a portion of the semiconductor substrate exposed through the second opening using the mask pattern as an etch mask. The trench is substantially narrower than the second opening and has a sidewall that has a second inclination angle that is substantially larger than the first inclination angle.

In further embodiments of the present invention, an insulating layer may be formed in the first opening, the second opening and the trench.

In still further embodiments of the present invention, the portion of the semiconductor substrate exposed through the first opening may be removed using a wet etching process. The wet etching process may be performed using an etching solution including ammonia (NH₃), hydrogen peroxide (H₂O₂) and water (H₂O) and having a temperature of from about 70° C. to about 80° C.

In some embodiments of the present invention, forming the mask pattern may further include forming a pad oxide layer on the semiconductor substrate and forming a nitride layer on the pad oxide layer. A photoresist pattern may be formed on the nitride layer and the photoresist pattern may at least partially expose the nitride layer. The nitride layer pattern and a preliminary pad oxide layer pattern may be formed by etching the nitride layer and the pad oxide layer using the photoresist pattern as an etch mask. An edge portion of the preliminary pad oxide layer pattern may be removed to form the pad oxide layer pattern having the line width substantially smaller than that of the nitride layer pattern.

In further embodiments of the present invention, the edge portion of the preliminary pad oxide layer pattern may be removed by a wet etching process. The wet etching process may be performed using a diluted hydrogen fluoride (HF) solution or a limulus amebocyte lysate (LAL) solution that includes ammonium fluoride (NH4F) hydrogen fluoride (HF) and water (H2O).

In still further embodiments of the present invention, the mask pattern may be preceded by forming the second opening and followed by partially etching a portion of the semiconductor substrate exposed through the mask pattern.

In some embodiments of the present invention, the method further includes forming an insulating layer pattern by partially removing an upper portion of the insulating layer until at least a portion of an upper face of the nitride layer is exposed.

Although embodiments of the present invention are primarily discussed above with respect to trench isolation methods, methods of forming gate structure of semiconductor devices and methods of manufacturing non-volatile memory devices are also provided herein.

### BRIEF DESCRIPTION OF THE DRAWINGS

FIGS. 1 through 6 are cross-sections illustrating trench isolation methods according to some embodiments of the present invention.

FIGS. 7 through 10 are cross-sections illustrating methods of forming gate structures according to some embodiments of the present invention.

FIGS. 10 to 13 are cross-sections illustrating methods of fabricating non-volatile memory devices according to some embodiments of the present invention.

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that although the terms first and second are used herein to describe various elements, these elements should not be limited by these terms. These terms are only used to distinguish one element from another element.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning in other words consistent with their meaning in the context of the relevant art and this specification and will not be interpreted in an idealized or overly formal sense unless expressly so defined herein.

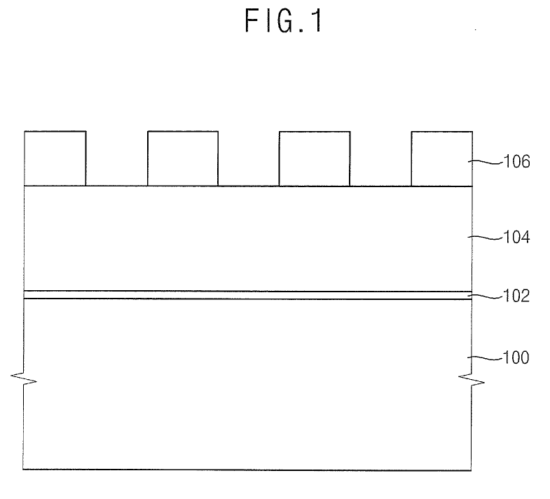

Some embodiments of the present invention will now be discussed with respect to FIGS. 1 through 13. FIGS. 1 through 6 are cross-sections illustrating processing steps in the fabrication of a trench isolation structure according to some embodiments of the present invention. Referring first to FIG. 1, a pad oxide layer 102 is formed on a semiconductor substrate 100. The pad oxide layer 102 may be formed using, for example, a thermal oxidation process or a chemical vapor deposition (CVD) process, such that the pad oxide layer 102 has a relatively thin thickness.

As further illustrated in FIG. 1, a nitride layer 104 is formed on the pad oxide layer 102. The nitride layer 104 may include, for example, silicon nitride. In addition, the nitride layer 104 may be formed using, for example, a low pressure chemical vapor deposition (LPCVD) process or a plasma enhanced chemical vapor deposition (PECVD) process.

A photoresist pattern 106 is formed on the nitride layer 104 by using, for example, a photolithography process. The nitride layer 104 may be at least partially exposed through the photoresist pattern 106. An isolation region may be subsequently formed at the exposed portions of the nitride layer 104 through the photoresist pattern 106. In addition, a portion of the semiconductor substrate 100 covered by the photoresist pattern 106 may correspond to an active region thereof.

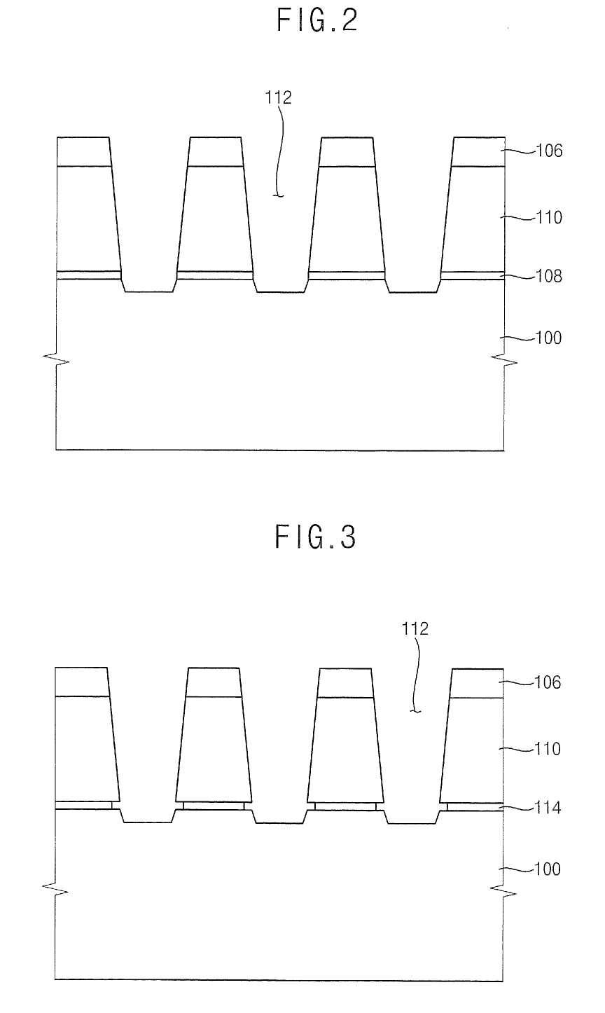

Referring now to FIG. 2, the nitride layer 104 and the pad oxide layer 102 are successively etched using the photoresist pattern 106 as an etch mask to form a preliminary mask pattern including a nitride layer pattern 110 and a preliminary pad oxide layer pattern 108. The etching process may be, for example, a plasma dry etching process or a reactive ion etching process.

A first opening 112, exposing at least a portion of the semiconductor substrate 100, may be formed by shaping the preliminary mask pattern. The semiconductor substrate 100 may be partially exposed from a bottom face of the first opening 112. In addition, the exposed portion of the semiconductor substrate 100 through the first opening 112 may be further etched after the preliminary mask pattern is formed.

Referring now to FIG. 3, an edge portion of the preliminary pad oxide layer pattern 108 is removed so that the preliminary pad oxide layer pattern 108 may be transformed into a pad oxide layer pattern 114 that has a line width substantially smaller than that of the preliminary pad oxide layer pattern 108.

The edge portion of the preliminary pad oxide layer pattern 108 may be removed using, for example, a wet etching process. An etching solution used in the wet etching process may be, for example, a diluted hydrogen fluoride (HF) solution or a limulus amebocyte lysate (LAL) solution that includes ammonium fluoride (NH₄F), hydrogen fluoride (HF) and water (H₂O).

The wet etching process may be performed using the etching solution for about, for example, thousands of seconds to remove the edge portion of the preliminary pad oxide layer pattern 108 to about 50 Å. Thus, a mask pattern having the pad oxide layer pattern 114 and the nitride layer pattern 110 that has a line width substantially larger than that of the pad oxide layer pattern 114 may be formed.

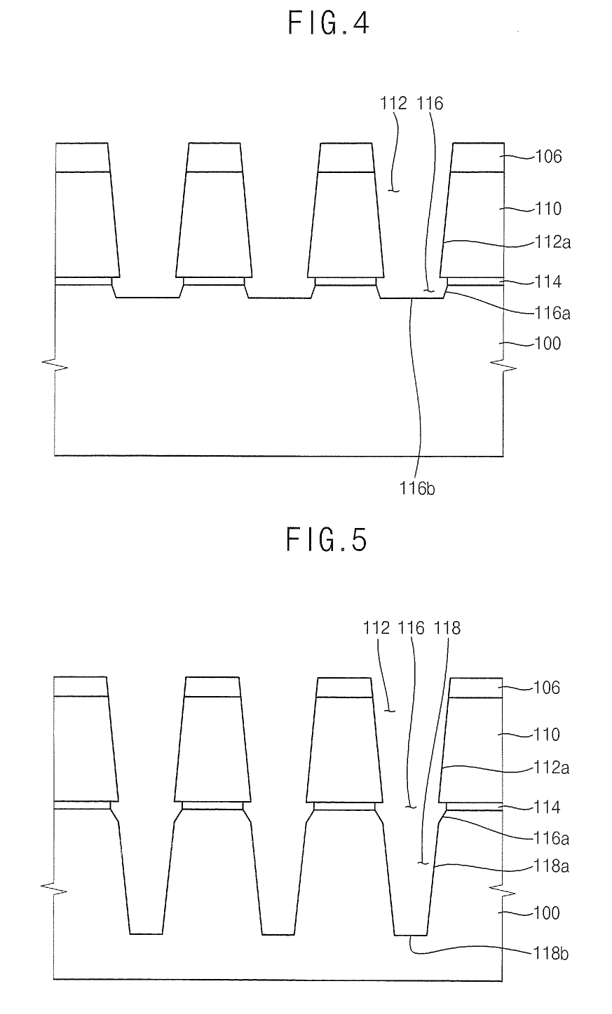

Referring now to FIG. 4, a portion of the semiconductor substrate 100 exposed through the pad oxide layer pattern 114 may be partially removed to form a second opening 116 connected to the first opening 112. A sidewall 116a of the second opening 116 may have a first inclination angle. The first inclination angle may correspond to an angle between the sidewall 116a of the second opening 116 and a bottom face 116b of the second opening 116.

The portion of the semiconductor substrate 100 exposed through the pad oxide layer pattern 114 may be removed using, for example, a wet etching process. The wet etching process may be performed using, for example, a standard cleaning 1 (SC1) solution. The SC1 solution may include ammonia (NH₄OH), hydrogen peroxide (H₂O₂) and water (H₂O). In addition, a temperature of the SC1 solution may be from about 70° C. to about 80° C.

The temperature of the SC1 solution may determine an etch rate. According to some embodiments of the present invention, an etch rate with respect to the semiconductor substrate 100 including silicon may be reduced by using the SC1 solution having a relatively high temperature of from about 70° C. to about 80° C. That is, an etch rate of the semiconductor substrate 100 may be effectively controlled by adjusting a temperature of the SC1 solution.

The sidewall 116a of the second opening 116 formed using the SC1 solution and etching the exposed portion of the semiconductor substrate 100 may have the first inclination angle substantially smaller than that of a sidewall 112a of the first opening 112. In some embodiments of the present invention, the portion of the semiconductor substrate 100 having the first inclination angle may correspond to an edge portion of the active region making contact with the isolation region that is subsequently formed. Thus, the edge portion of the isolation region making contact with the isolation region may be slightly inclined.

Referring now to FIG. 5, an exposed portion of the substrate 100 may be etched using the mask pattern as an etch mask to form a trench 118 connected to the second opening 116. A width of the trench 118 may be substantially smaller than that of the second opening 116. Furthermore, a sidewall 118a of the trench 118 may be substantially steeper than the sidewall 116a of the second opening 116.

In particular, a plasma dry etching process is performed on the semiconductor substrate 100 by using the mask pattern as an etch mask to form the trench 118. In some embodiments of the present invention, the width of the trench 118 may become substantially narrow from an upper portion of the trench 118 toward a lower portion of the trench 118. The trench may be narrow from the upper portion toward the lower potion because the trench 118 may be formed using, for example, the plasma dry etching process. Thus, the sidewall 118a of the trench 118 may have a second inclination angle substantially larger than the first inclination angle. In some embodiments of the present invention, the second inclination angle may substantially correspond to an angle between the sidewall 118a of the trench 118 and a bottom face 118b of the trench 118.

A thermal oxidation layer (not shown) and an insulating liner (not shown) are successively formed on an inner face of the trench 118 after the trench 118 is formed. The thermal oxidation layer may have a relatively thin thickness. The thermal oxidation layer may be formed by, for example, oxidizing the inner face of the trench 118 so that damage caused by performing the dry etching process may be cured. The insulating liner may be formed on the thermal oxidation layer and the mask pattern. A thickness of the insulating liner may be about hundreds of angstroms. The insulating liner may decrease a stress generated in a silicon oxide layer subsequently filling up the trench 118 to form an isolation layer. Furthermore, the insulating liner may reduce the likelihood that impurity ions will penetrate into the isolation region. In some embodiments of the present invention, the insulating liner may be formed using a material having a relatively high etching selectivity with respect to the silicon oxide layer under predetermined etching conditions. For example, the insulating liner may be formed using silicon nitride (SiN).

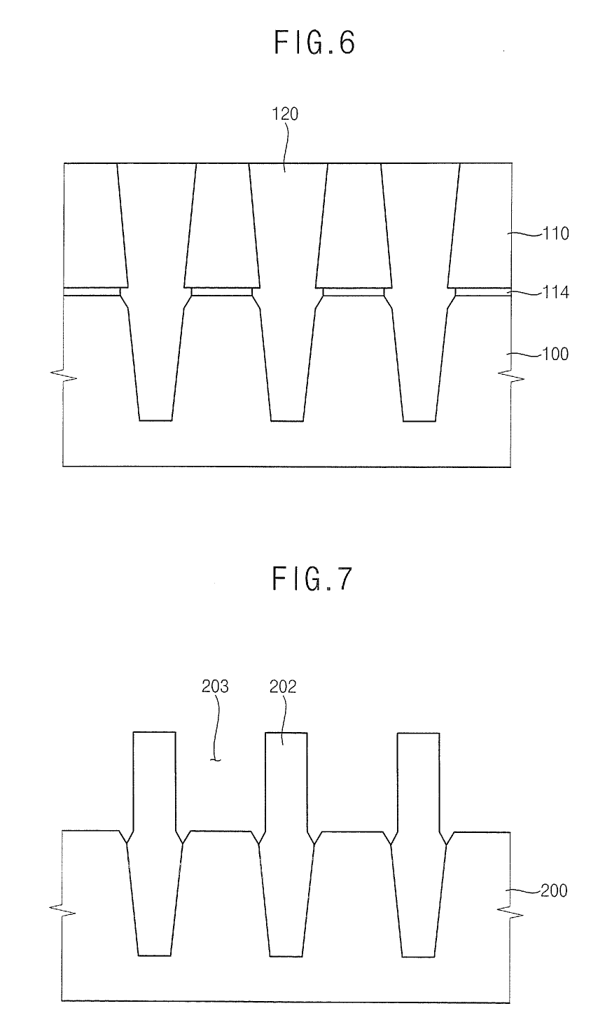

Referring now to FIG. 6, an insulating layer (not shown) including silicon oxide may be formed in the first opening 112, the second opening 116 and the trench 118. The silicon oxide included in the insulating layer may have relatively superior gap filling characteristics. For example, the silicon oxide may be, for example, undoped silicate glass (USG), O₃-tetra ethyl ortho silicate undoped silicate glass (O₃-TEOS USG) or high density plasma (HDP) oxide. The insulating layer may be formed using, for example, a chemical vapor deposition (CVD) process.

An annealing process may be performed on the insulating layer at an environment having a relatively high temperature of from about 800° C. to about 1050° C. and an inert gas. In embodiments of the present invention where the annealing process is performed on the insulating layer, the insulating layer may become dense. Thus, a wet etch rate may decrease while a cleaning process is subsequently performed.

The insulating layer may be planarized by an etch-back or a chemical mechanical polishing (CMP) process until at least a portion of the mask pattern is exposed. Thus, the insulating layer may be transformed into an insulating layer pattern 120 located in the trench 118.

Although not illustrated in the figures, the mask pattern is removed so that a portion of the semiconductor substrate 100 corresponding to the active region may be exposed.

A center portion of the active region may be relatively planar. Furthermore, an edge portion of the active region may have the first inclination angle. Thus, in case that a thermal oxidation process is performed on the edge portion of the active region, a stress due to a three dimensional effect may not be generated. As a result, when an oxide layer is subsequently formed on the active region by using a thermal oxidation process, a portion of the oxide layer located on the edge portion of the active region may have substantially the same thickness as a portion of the oxide layer located on the center portion of the active region. In some embodiments of the present invention, the oxide layer may be used as a gate oxide layer of a gate structure, a tunnel oxide layer of a non-volatile memory device, and the like without departing from the scope of the present invention.

Referring now to FIGS. 7 through 10, methods of manufacturing a gate structure using the method of forming a trench isolation process discussed above with respect to FIGS. 1 through 6 will be discussed. FIGS. 7 to 10 are cross-sections illustrating methods of forming a gate structure according to some embodiments of the present invention.

Referring now to FIG. 7, processes substantially the same as those illustrated in FIGS. 1 to 6 are performed so that an insulating layer pattern 202 and a mask pattern (not shown) may be formed on a substrate 200. The insulating layer pattern 202 may define an active region having a center portion and an edge portion. The center portion may be relatively planar. In addition, the edge portion may be slightly inclined. The mask pattern includes a pad oxide layer pattern and a nitride layer pattern that are successively stacked.

The mask pattern is then removed so that a third opening 203 exposing the active region may be formed. In particular, the nitride layer pattern included in the mask pattern is removed by a wet etching process using phosphoric acid (H₃PO₄). Thereafter, the pad oxide layer pattern included in the mask pattern is removed using a wet etching process using a dilute hydrogen fluoride (HF) solution.

In some embodiments of the present invention, the insulating layer pattern 202 may be partially removed while the pad oxide layer pattern is removed because the insulating layer pattern 202 is formed from a silicon oxide. Thus, an edge portion of the active region having a first inclination angle may be also exposed from the third opening 203.

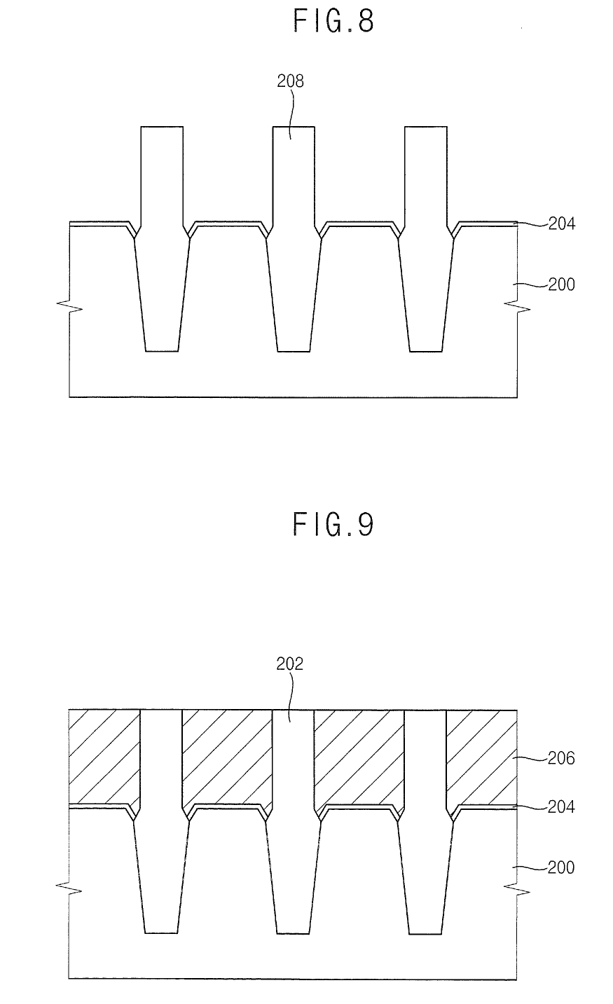

Referring now to FIG. 8, a gate oxide layer 204 may be formed on center portion and edge portions of the active region, i.e., a portion of the semiconductor substrate exposed from the bottom face of the third opening 203.

The gate oxide layer 204 may be formed using, for example, a thermal oxidation process. A gate oxide layer 204 may be formed on the center portion and edge portions of the active region. The gate oxide layer 204 may have a relatively uniform thickness because the edge portion of the active region is slightly inclined.

Referring now to FIG. 9, a conductive layer (not shown) is formed on the insulating layer pattern 202 to fill up the third opening 203. The conductive layer may be subsequently used as a gate electrode 206. The conductive layer may include doped polysilicon or metal.

Thereafter, an upper portion of the conductive layer may be partially removed such that an upper face of the insulating layer pattern 202 may be exposed. Thus, the gate electrode 206 may be formed.

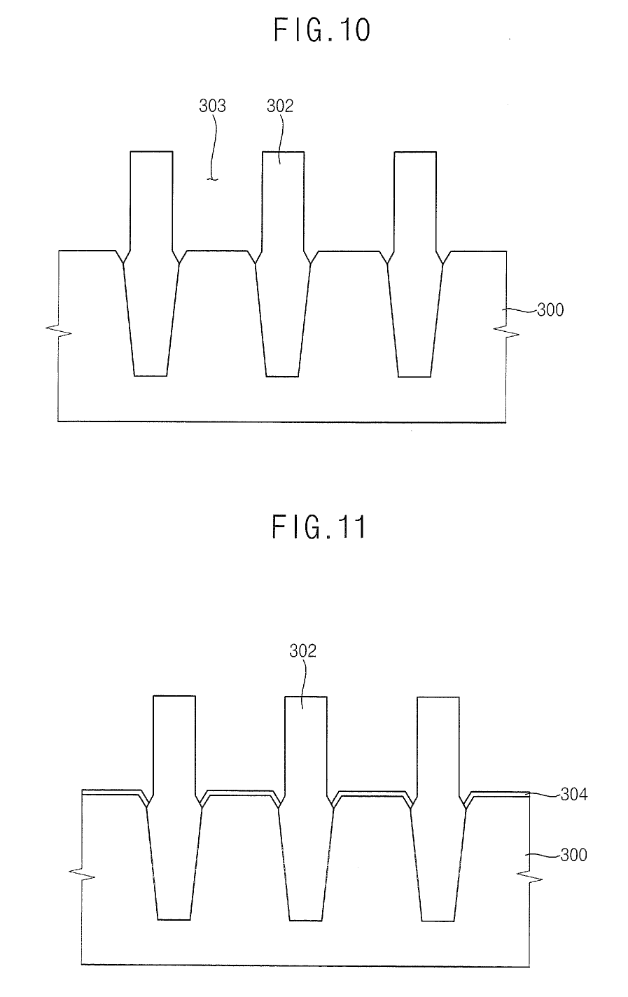

Referring now to FIGS. 10 through 13, methods of manufacturing non-volatile memory devices using the trench isolation process discussed above with respect to FIGS. 1 through 6 will be discussed. FIGS. 10 to 13 are cross-sections illustrating methods of manufacturing non-volatile memory devices according to some embodiments of the present invention.

Referring now to FIG. 10, processes substantially the same as those discussed above with respect to FIGS. 1 to 6 are performed so that an insulating layer pattern 302 and a mask pattern (not shown) may be formed at a substrate 300. The insulating layer pattern 302 may define an active region having a center portion and an edge portion. The center portion may be relatively planar, and the edge portion may be slightly inclined. The mask pattern may include a pad oxide layer pattern and a nitride layer pattern that are subsequently stacked. In some embodiments of the present invention, the thickness of the mask pattern may be substantially larger than a height of a floating gate electrode that is subsequently formed.

Thereafter, the mask pattern is removed so that the active region may be exposed. In some embodiments of the present invention, a third opening 303 may be formed between the insulating layer patterns 302. In particular, the nitride layer pattern included in the mask pattern is removed by a wet etching process using phosphoric acid (H₃PO₄). Thereafter, the pad oxide layer pattern included in the mask pattern is removed by a wet etching process using a dilute hydrogen fluoride (HF) solution.

While the pad oxide layer pattern is removed, the insulating layer pattern 302 may be partially removed. In other words, the insulating layer pattern 302 may be partially removed while etching the pad oxide layer pattern because the insulating layer pattern 302 includes silicon oxide. As a result, an edge portion of the active region having a first inclination angle may be also exposed from a bottom face of the third opening 303.

Furthermore, a process for enlarging the active region may be performed such that the edge portion of the active region is fully exposed. In the process for enlarging the active region, a sidewall of the insulting layer pattern 302 may be partially removed. As discussed above, the active region may include the center portion that is relatively planar and the edge portion that has a first inclination angle.

Referring now to Figure, a tunnel oxide layer 304 is formed on the active region having the center portion and the edge portion. To form the tunnel oxide layer 304, a radical oxidation process is initially performed. Thereafter, an annealing process is performed in-situ with nitric oxide (NO). In some embodiments of the present invention, the tunnel oxide layer 304 formed on the center portion and the edge portion may have a relatively uniform thickness because the active region has the center portion that is relatively planar and the edge portion that has a slight incline.

The possibility of current leakage due to an irregular thickness of the tunnel oxide layer 304 may be decreased by forming the tunnel oxide layer 304 on the active region, thereby having a relatively uniform thickness.

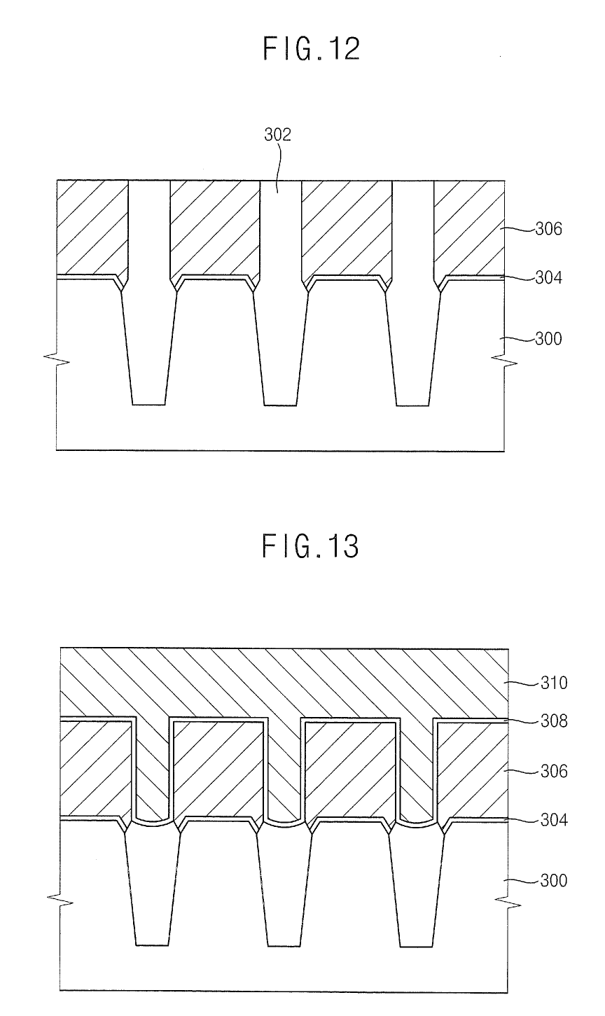

Referring now to FIG. 12, a floating gate electrode 306 is formed on the tunnel oxide layer 304. In particular, a first conductive layer (not shown) is formed on the insulating layer pattern 302 in the third opening 303 having a bottom face on which the tunnel oxide layer 304 is formed. An upper portion of the first conductive layer is removed until an upper face of the insulating layer pattern 302 is exposed. Thus, the floating gate electrode 306 having a relatively planar shape may be formed.

The insulating layer pattern 302 may be partially removed such that an outer sidewall of the floating gate electrode 306 is exposed. Although not illustrated in the figures, a floating gate electrode having a substantial “U” shape may be formed on the tunnel oxide layer 304 such that the floating gate is formed along an inner surface of the third opening. In particular, a first conductive layer formed along the inner surface of the third opening may be formed such that the third opening is not completely filled with the first conducive layer. A sacrificial layer may be formed in the third opening. The first conductive layer is partially removed such that an upper face of the insulating layer pattern 302 is exposed. Thus, the floating gate electrode having a substantial “U” shape may be formed.

Referring now to FIG. 13, a dielectric layer 208 is formed on the floating gate electrode 306. In some embodiments of the present invention, the dielectric layer may be, for example, an oxide-nitride-oxide (ONO) layer, a metal layer, and the like. Thereafter, a second conductive layer 210 may be formed on the dielectric layer. The second conductive layer 210 may be subsequently transformed into a control gate electrode.

Although not illustrated in the figures, the second conductive layer 210, the dielectric layer and the floating gate electrode 306 are etched so that a non-volatile memory device including the control gate electrode (not shown), a dielectric layer pattern (not shown) and a floating gate electrode 306 may be formed.

According to some embodiments of the present invention, a pad oxide layer is partially removed by a diluted hydrogen fluoride solution. An exposed portion of a semiconductor substrate is removed by a standard cleaning 1 (SC1) solution. Thus, an active region having a center portion that is relative planar and a slightly inclined edge portion may be efficiently formed. As a result, an oxide layer having a relatively uniform thickness may be continuously formed on the active region by an oxidation process.

When the oxide layer is used as a tunnel oxide layer of a non-volatile memory device or a gate oxide layer of a gate electrode, the likelihood of a current leakage decreasing reliability of a semiconductor device may be reduced because a portion of the oxide layer formed on the edge portion and a portion of the oxide layer formed on the center portion have substantially the same thickness.

In the drawings and specification, there have been disclosed typical embodiments of the invention and, although specific terms are employed, they are used in a generic and descriptive sense only and not for purposes of limitation, the scope of the invention being set forth in the following claims.

That which is claimed is:

1. A method of trench isolation in a semiconductor device, the method comprising:
forming a mask pattern on a semiconductor substrate, the mask pattern defining a first opening that at least partially exposes the semiconductor substrate and including a pad oxide layer and a nitride layer pattern on the pad oxide layer pattern and the nitride layer having a line width substantially larger than the pad oxide layer pattern;
forming a second opening that is connected to the first opening by at least partially removing a portion of the semiconductor substrate exposed through the first opening, the second opening having a sidewall that has a first inclination angle and at least partially exposing the semiconductor substrate; and
forming a trench connected to the second opening by etching a portion of the semiconductor substrate exposed through the second opening using the mask pattern as an etch mask, the trench being substantially narrower than the second opening and having a sidewall that has a second inclination angle that is substantially larger than the first inclination angle.

2. The method of claim 1, further comprising forming an insulating layer in the first opening, the second opening and the trench.

3. The method of claim 2, wherein the portion of the semiconductor substrate exposed through the first opening is removed using a wet etching process.

4. The method of claim 3, wherein the wet etching process is performed using an etching solution including ammonia (NH₃), hydrogen peroxide (H₂O₂) and water (H₂O) and having a temperature of from about 70° C. to about 80° C.

5. The method of claim 2, wherein forming the mask pattern comprising:
forming a pad oxide layer on the semiconductor substrate;
forming a nitride layer on the pad oxide layer;
forming a photoresist pattern on the nitride layer, the photoresist pattern at least partially exposing the nitride layer;
forming the nitride layer pattern and a preliminary pad oxide layer pattern by etching the nitride layer and the pad oxide layer using the photoresist pattern as an etch mask; and
removing an edge portion of the preliminary pad oxide layer pattern to form the pad oxide layer pattern having the line width substantially smaller than that of the nitride layer pattern.

6. The method of claim 5, wherein the edge portion of the preliminary pad oxide layer pattern is removed by a wet etching process.

7. The method of claim 6, wherein the wet etching process is performed using a diluted hydrogen fluoride (HF) solution or a limulus amebocyte lysate (LAL) solution that includes ammonium fluoride (NH₄F) hydrogen fluoride (HF) and water (H₂O).

8. The method of claim 2, wherein forming the mask pattern is preceded by forming the second opening and followed by partially etching a portion of the semiconductor substrate exposed through the mask pattern.

9. The method of claim 1, further comprising:
forming an insulating layer pattern by partially removing an upper portion of the insulating layer until at least a portion of an tipper face of the nitride layer is exposed.

10. A method of forming a gate structure of a semiconductor device, the method comprising:
forming a mask pattern on a semiconductor substrate, the mask pattern defining a first opening that at least partially exposes the semiconductor substrate and including a pad oxide layer pattern and a nitride layer pattern that are successively stacked and the nitride layer pattern having a line width substantially larger than that of the pad oxide layer pattern;
forming a second opening that is connected to the first opening by partially removing a portion of the semiconductor substrate exposed through the first opening, the second opening having a sidewall that has a first inclination angle and exposing at least a portion of the semiconductor substrate;
forming a trench that is connected to the second opening by etching a portion of the semiconductor substrate exposed through the second opening using the mask pattern as an etch mask, the trench being substantially narrower than the second opening and having a sidewall that has a second inclination angle that is substantially larger than the first inclination angle;
forming an insulating layer in the first opening, the second opening and the trench;
forming an insulating layer pattern by removing an upper portion of the insulating layer until at least a portion of an upper face of the mask pattern is exposed;
forming a third opening partially exposing the semiconductor substrate by removing the mask pattern;
forming a gate oxide layer on center and edge portions of the semiconductor substrate exposed from a bottom face of the third opening; and
forming a gate electrode on the gate oxide layer.

11. A method of manufacturing a non-volatile memory device, the method comprising:
forming a mask pattern on a semiconductor substrate, the mask pattern defining a first opening that at least partially exposes the semiconductor substrate and including a pad oxide layer pattern and a nitride layer pattern that are successively stacked and the nitride layer pattern having a line width substantially larger than that of the pad oxide layer pattern;
forming a second opening that is connected to the first opening by partially removing a portion of the semiconductor substrate exposed through the first opening, the second opening having a sidewall that has a first inclination angle and exposing at least a portion of the semiconductor substrate;
forming a trench that is connected to the second opening by etching a portion of the semiconductor substrate exposed through the second opening using the mask pattern as an etch mask, the trench being substantially narrower than the second opening and having a sidewall that has a second inclination angle that is substantially larger than the first inclination angle;
forming an insulating layer in the first opening, the second opening and the trench;
forming an insulating layer pattern by removing an upper portion of the insulating layer until at least a portion of an upper face of the mask pattern is exposed;
forming a third opening partially exposing the semiconductor substrate by removing the mask pattern;
forming a tunnel oxide layer on center and edge portions of the semiconductor substrate exposed through a bottom face of the third opening; and
forming a floating gate electrode, a dielectric layer and a control gate electrode on the tunnel oxide layer.

12. The method of claim 11, wherein the insulating layer includes an oxide.

13. The method of claim 11, further comprising forming a fourth opening that is substantially wider than the third opening by partially removing the insulating layer pattern.
